(19) United States
(12) Patent Application Publication
(10) Pub. No.: US 2017/0169932 A1
(43) Pub. Date: Jun. 15, 2017

(54) MAGNETIC MATERIAL COATED WIRE INDUCTOR

(71) Applicants: William J. Lambert, Chandler, AZ (US); Kevin O'Brien, Portland, OR (US); Omkar Karhade, Chandler, AZ (US)

(72) Inventors: William J. Lambert, Chandler, AZ (US); Kevin O'Brien, Portland, OR (US); Omkar Karhade, Chandler, AZ (US)

(21) Appl. No.: 14/969,861

(22) Filed: Dec. 15, 2015

(51) Int. Cl. H01F 27/28; H01F 41/12; C23C 14/35; H01F 27/32

(52) U.S. Cl. CPC H01F 27/2823; H01F 27/32; H01F 41/12; C23C 14/35

(57) ABSTRACT

Apparatus and methods are provided for a wire based inductor component. In an example, an inductor apparatus can include a wire and a plurality of individual layers of magnetic material surrounding the wire.

### TECHNICAL FIELD

The disclosure herein relates generally to inductors and more particularly to wire based inductor components.

### BACKGROUND

Electronics continue to be developed that are smaller yet more powerful computationally and functionally. Opportunities and challenges continue to arise that push the creative enterprise of electronic designers to provide small powerful electronic products that provide desired user functionality in a convenient package. Passive electronics have characteristics that can rely on a physical dimension to attain an acceptable performance level. The physical characteristic can limit size reduction in some configurations or can limit handling and integration into an integrated circuit in other configurations.

### BRIEF DESCRIPTION OF THE DRAWINGS

In the drawings, which are not necessarily drawn to scale, like numerals may describe similar components in different views. Like numerals having different letter suffixes may represent different instances of similar components. Some embodiments are illustrated by way of example, and not limitation, in the figures of the accompanying drawings in which:

FIGS. 1A and 1B illustrate generally a cross-section view of a magnetic material coated wire inductor according to various examples of the present subject matter.

FIG. 2 illustrates an apparatus associated with an example method of coating a wire to form a magnetic material coated wire inductor

FIG. 3 illustrates generally a flowchart of an example method of making a magnetic material coated wire inductor using the apparatus of FIG. 2

FIG. 4 illustrates a flowchart of an example method for producing a magnetic material coated wire inductor using chemical vapor deposition.

FIG. 5 illustrates a flowchart of an additional example method of fabricating and assembling the magnetic layers of a magnetic material coated wire inductor.

FIGS. 6A-6E illustrate generally an example method and structures associated with developing inductor components using magnetic material coated wire inductors.

FIG. 7 illustrates generally an integrated circuit system including an example inductive component.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

Recent developments in magnetic core inductor (MCI) technology provide the possibility of scaling inductors for integrated voltage regulators into much smaller areas and volumes than possible with air core inductors (ACIs). However, the current technology has some drawbacks. For example, processing can require substantial material costs. Those costs can include a silicon wafer that is used as a base for the inductor and is typically ground away to make the inductor thinner, and the processing can include multiple mask layers with numerous alternating deposition and etch steps. Another drawback is that electrical performance of the inductors can be limited by the processing. For example, because of warpage concerns, metal thickness on the wafer can be limited thus limiting reduction of DC resistance. Also, the formation of a magnetic via at the edge of the inductor can introduce large losses at higher frequencies due to the planar topology of the inductor as opposed to limitations of the material itself. Additionally, planar structures associated with these recent developments in inductor technology can require a large planar area even though the volume of the inductor itself is miniscule.

The present inventors have recognized a method and resulting structure for creating passive MCI components without some of the drawbacks of planar MCIs as discussed above. In certain examples, a method can include directly coating a cylindrical wire with polarized magnetic material to create a magnetic material coated wire inductor. In certain examples, arrays of the magnetic material coated wire inductors can then be arranged and coated with an epoxy for examples to form a low cost inductor component compatible with high volume assembly. Methods associated with the present subject matter would not require an expensive silicon wafer carrier. In certain examples, etching can be eliminated or significantly reduced. In some examples, the cylindrical wire can have a diameter commensurate with the width of a trace in the planar MCI topology but provide a DC resistance that is on the order of a quarter of the DC resistance of the trace. In some examples, AC, or high frequency, resistance of the present subject matter can be on the order of one-half of the AC resistance of the planar MCI technology. In certain applications, improvements such as these can translate in to improved efficiency of a integrated voltage regulator, decrease power dissipation of the inductor component, and better thermal performance for high current applications. In certain examples, inductor components according to the present subject matter can allow for smaller minimum planar footprint while accommodating the same current handling capacity of the planar MCI technology.

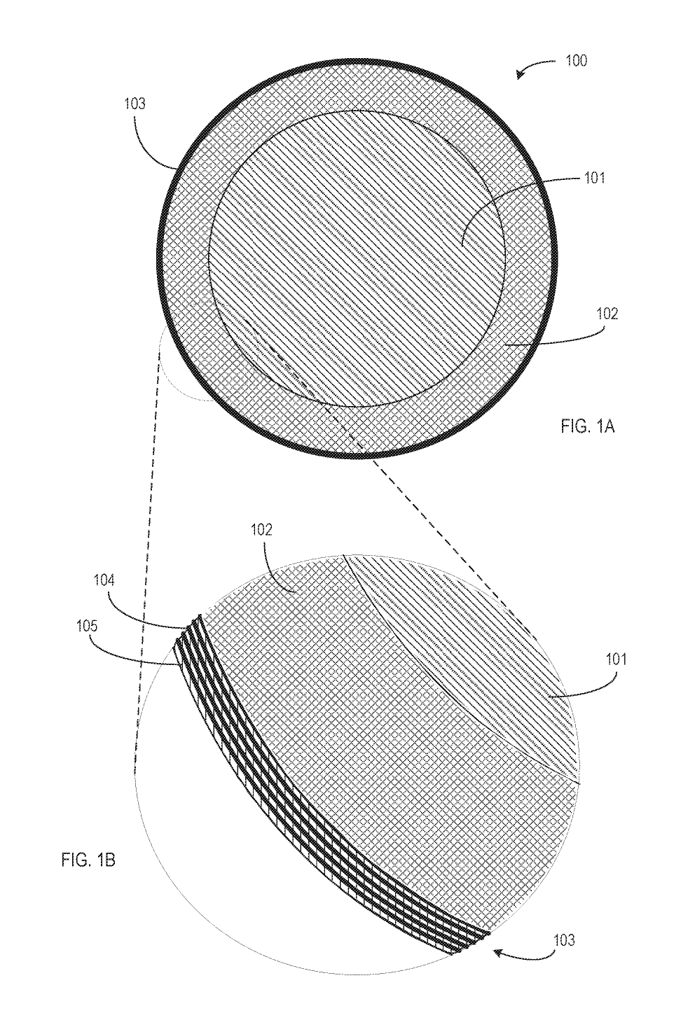

FIGS. 1A and 1B illustrate generally a cross-section view of a magnetic material coated wire inductor 100 according to various examples of the present subject matter. In certain examples, the magnetic material coated wire inductor 100 includes a length of round conductive wire 101 surrounded by alternating layers 103 of insulation and high permeability magnetic material 102, 104, 105. In certain examples, the magnetic material coated wire inductor 100 can include a cylindrical wire 101, a first insulation material 102, and alternating layers 103 of magnetic material 104 and second insulation material 105. In certain examples, the wire 101 can be a copper wire or a silver wire. In some examples, the wire 101 can have substantially circular cross section and can have a diameter of about 70 micrometers (μm). In some examples, the diameter of the wire can be between 30 μm and 300 μm.

In some examples, the first insulation material 102 can include a polymer based insulating material. In some examples, the first insulation material 102 can include, but is not limited to a resist material such a photoresist material. In some examples, the wire 101 can include a pair of substantially parallel wires, for example, to produce a coupled inductor. In some examples, the wire 101 or the pair of wires can be cleaned and coated with the first insulation material 102. In some examples, the thickness of the first insulation material 102 can be between 1 μm and 100 μm or more. In some examples, the first insulation material 102 can be applied to provide a uniform thickness of first insulation material 102.

Relative permeability, sometimes denoted by the symbol μᵣ, is the ratio of the permeability of a specific medium to the permeability of free space μ₀. In some examples, the magnetic material 104 can include high permeability magnetic material such as, but not limited to, cadmium-zinc-telluride (CZT), cobalt-zirconium-tantalum-boron (CZTB), permalloy (Py), iron, nickel, or combinations thereof. In certain examples, a high permeability material includes a magnetic material having a relative permeability of up to 100 uᵣ. In some examples, a high permeability material includes a magnetic material having a relative permeability of up to 200 uᵣ or more, such as cobalt (250 uᵣ). In some examples, a high permeability material includes a magnetic material having a relative permeability of up to 500 uᵣ or ore such as Nickel (600 uᵣ). In some examples, a high permeability material includes a magnetic material having a relative permeability of up to 1000 uᵣ. In some examples, a high permeability material can include a magnetic material such as iron that can have a magnetic relative permeability of up to 200,000 uᵣ. Referring to FIG. 1B, in certain examples, the alternating layers 103 of magnetic material 104 and second insulation material 105 can include layers of magnetic material 104 that in a cross section view completely surround the wire 101. In certain examples, the alternating layers 103 include at least one layer of magnetic material 104. In certain examples, the alternating layers 103 include at least two layers of magnetic material 104. In certain examples, the alternating layers 103 include more than three layers of magnetic material 104. In some examples, a thickness of the magnetic material 104 in an alternating layer 103 of magnetic material 104 and second insulation material 105 can be about 100 nanometers (nm) to about 1 μm. In certain examples, the insulation material 105 of the alternating layers 103 of magnetic material 104 and insulation material 105 can include, but is not limited to Aluminum Nitride (AlN). In certain examples, the thickness of an alternating layer 103 of second insulation material 105 is about 5 nm to about 100 nm. In certain examples, upon completion, the alternating layers 103 of magnetic material 104 and insulation material 105 can have a combined thickness of 2 μm to 10 μm or more.

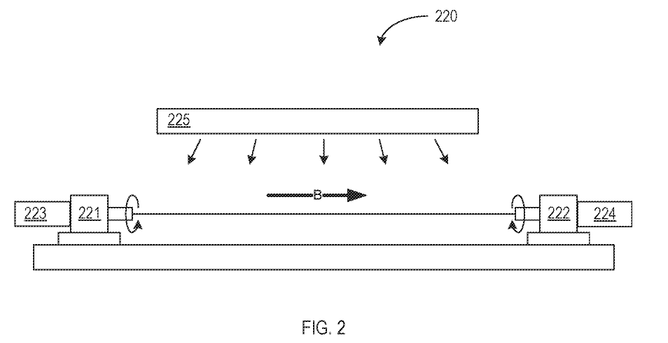

FIG. 2 illustrates an apparatus 220 associated with an example method of coating a wire to form a magnetic material coated wire inductor. In certain examples, the apparatus includes two spindles 221, 222 one or more motors 223, 224, sputtering and/or deposition equipment, including a sputtering target 225, and equipment for establishing a magnetic field or B-field. In certain example, the each spindle 221, 222 is capable of capturing and holding an end of the wire 201 and suspending the wire 201 between the spindles 221, 222. In certain examples, one or more motors 223, 224, and associated linkages can spin the wire 201 about an axis extending through the center of the circular cross-section of the wire 201. In some examples, the one or more motors 223, 224 can include a motor for each spindle and a controller (not shown) configured to synchronize the acceleration, constant spinning velocity and deceleration of the spindles 221, 222 to eliminate or minimize twisting the wire 201. In some examples, the motors 223, 224 can include, but are not limited to, stepper motors, servo motors, or combinations thereof.

Upon rotating the wire 201, alternating layers of insulation material and magnetic material can be applied to the wire 201. The combination of the wire rotation and use of the sputtering or deposition equipment can assist in applying each coat of material in a substantially uniform manner. In certain examples, the equipment for establishing a magnetic field (B) can be used to apply a magnetic field as the magnetic material is applied for each layer. The magnetic field allows the magnetic material to be polarized upon allocation to the preceding layer. Polarized magnetic material can provide better performance in certain applications of the magnetic material coated wire inductor.

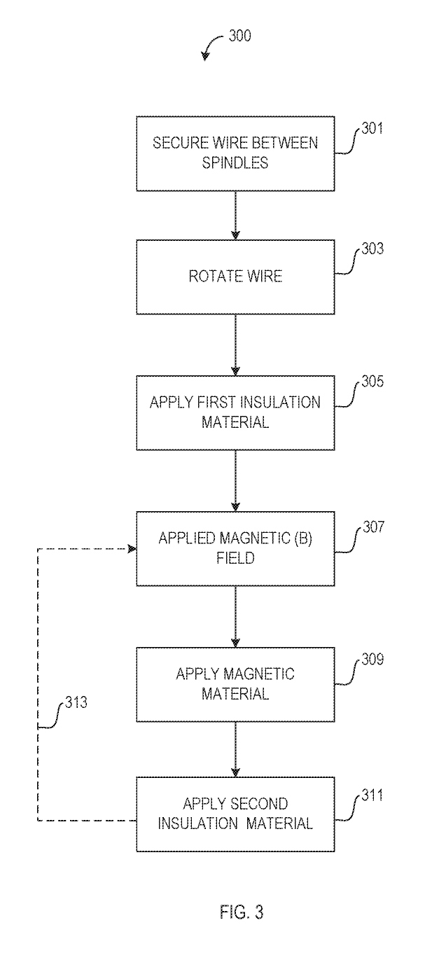

FIG. 3 illustrates generally a flowchart of an example method 300 of making a magnetic material coated wire inductor using the apparatus of FIG. 2. At 301, a wire is secured between a pair of spindles. At 303, the wire is rotated around an axis extending through the middle of a circular cross-section of the wire. At 305, a first insulation material is applied to the wire to form a first insulation layer. In some examples, the first insulation material is applied using sputtering. In some examples, the first insulation material can include a resist such as a photo-resist. At 307, a magnetic field is optionally created about the wire. At 309, a magnetic material is applied to the first insulation layer to form a first magnetic layer. In some examples, the magnetic material is applied using sputtering. In some examples, sputter rate control and rotation velocity control can ensure uniform coverage of the sputtered material as well as control of the layer thickness. In certain examples, the thickness of the magnetic material can be between 100 nm to 1 μm. At 311, a second insulation material is applied to the magnetic layer. In some examples, the second insulation material can include a resist, AlN, or combinations thereof. At 313, the process of applying the magnetic material and the second insulation material optionally can be repeated until the desired number of magnetic layers are applied.

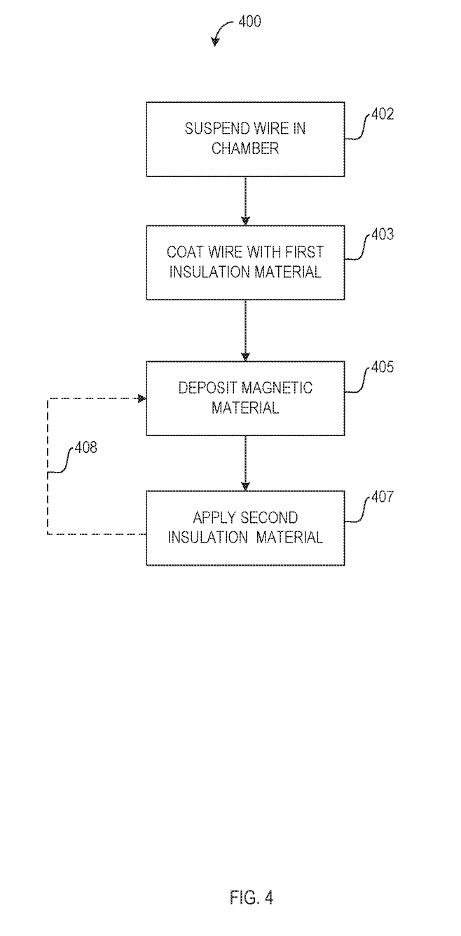

FIG. 4 illustrates a flowchart of an example method 400 for producing a magnetic material coated wire inductor using chemical vapor deposition. At 401, the wire is suspended in a deposition chamber. At 403, a first insulation material is applied to coat the wire. At 405, a magnetic material is applied via chemical vapor deposition. At 407, a second insulation material is applied to coat the magnetic material. At 408, application of the magnetic material and the second insulation material can be repeated until the desired number of magnetic material layers is attained.

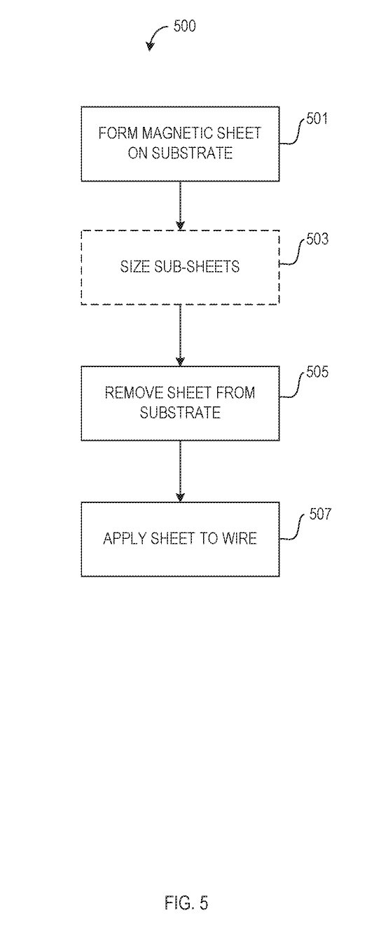

FIG. 5 illustrates a flowchart of an additional example method 500 of fabricating and assembling the magnetic layers of a magnetic material coated wire inductor. At 501, a sheet of magnetic material can be formed on a substrate. In certain examples, the substrate can include a resist or low adhesion surface upon which the pattern or sheet of magnetic material is formed or deposited. In certain examples, sheets of magnetic material can have a thickness of less than 10 μm. In some examples, this method can also be used to form sheets of insulator material. After formation ion the substrate, at 503, the sheet can optionally be patterned using sizes suitable for application on the wire. At 505, the magnetic material can then be removed from the substrate and, at 507, applied to the wire. In certain examples, the magnetic material can be removed from the substrate and applied to the wire by having the wire contact the sheet and turning the wire to allow the sheet to be lifted of the substrate and wrapped around the wire. It is understood that in reference to the example of FIG. 5, reference to the wire can include the actual wire and any previously formed insulation layers or magnetic layers. In some examples, the magnetic material can be removed from the substrate by a lift-off method such as by placing the substrate and magnetic material in a lift-off bath that allows the magnetic material to float off the substrate. The magnetic material can then be applied to the partially assembled magnetic material coated wire inductor by moving the partially assembled magnetic material coated wire inductor through the sheet that is suspended or floating in the lift-off bath. The partially assembled magnetic material coated wire inductor can then be coated or wrapped with the sheet via capillary forces by retracking or rolling the partially assembled magnetic material coated wire inductor.

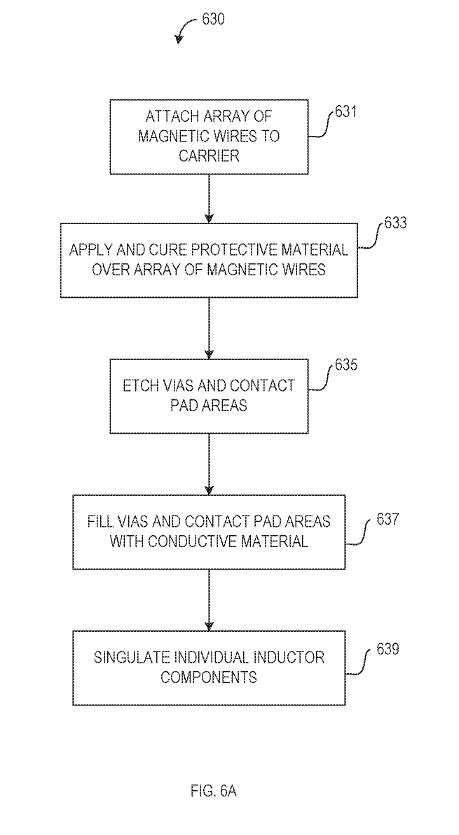

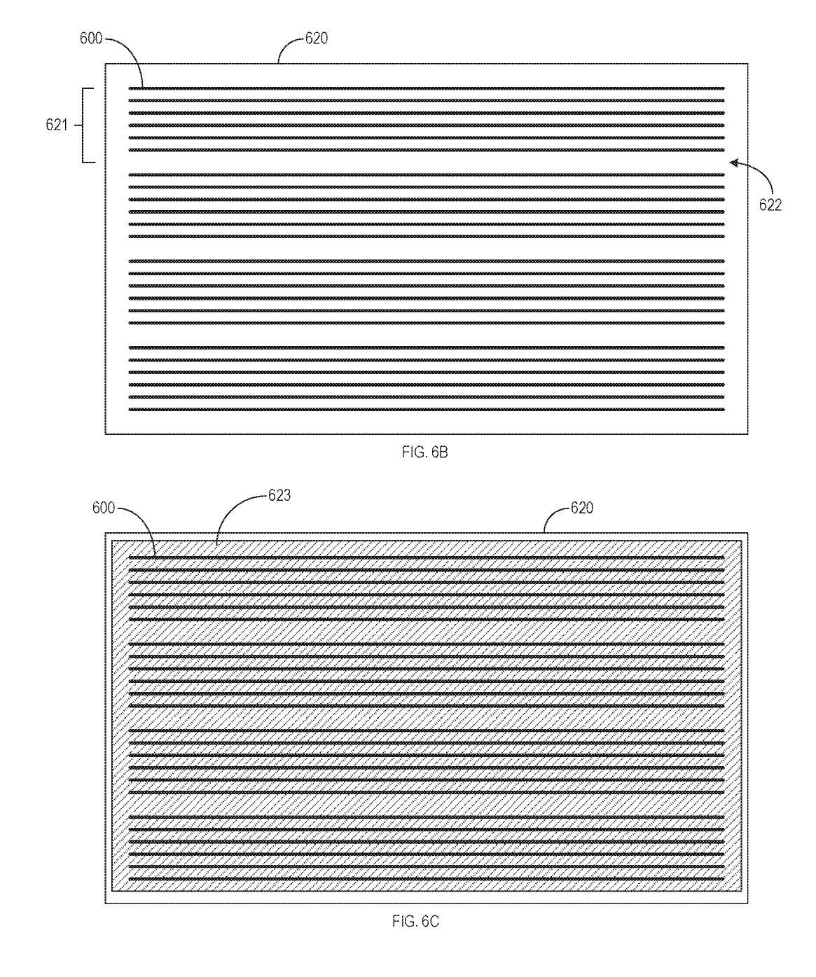

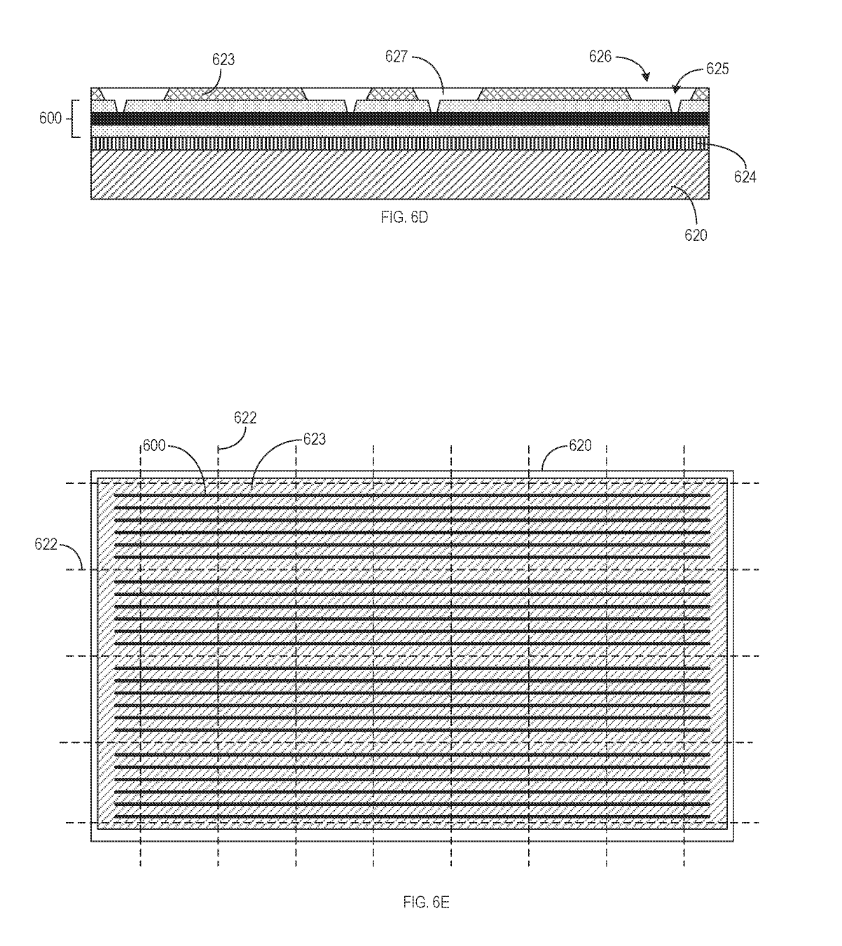

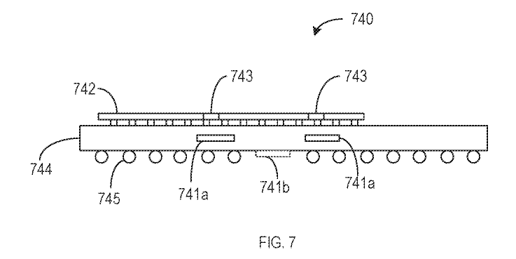

FIGS. 6A-6E illustrate generally an example method 630 and structures associated with developing inductor components using magnetic material coated wire inductors 600. In certain examples, at 631, a completed magnetic material coated wire inductor 600 can be attached to a temporary carrier 620. In certain examples, the temporary carrier 620 can include an adhesive 624 or an adhesive tape to allow the magnetic material coated wire inductors 600 to cling to the temporary carrier 620. In certain examples, groups of magnetic material coated wire inductors 621 can be separated by distance to allow for a cut-line 622 (FIG. 6B). After assembly of the magnetic material coated wire inductors 600 to the temporary carrier 620, at 633, an epoxy material 623 can be poured or molded over the magnetic material coated wire inductors 600 and cured. In certain examples, the epoxy material 623 can protect the magnetic material coated wire inductors 600 (FIG. 6C). In some examples, the epoxy material 623 can form the external packaging material of the inductor components. In certain examples, after the epoxy material is cured, at 635, vias 625 and pad openings 626 are formed in the outer layers of the magnetic material coated wire inductor 600 and the epoxy material 623 to allow for electrical connection of the magnetic material coated wire inductors 600 (FIG. 6D). In some examples, sidewalls of vias 625 can be coated with an insulating material to prevent unwanted connection or shorting of the magnetic layers. In certain examples, at 637, electrically conductive material 627, such as copper, for example, can be applied to fill the vias 625 and form contact pads in the pad openings 626. In certain example, at 639, the magnetic material coated wire inductors 600, temporary carrier 620 and epoxy material 623 can be cut along the cut-lines 622 to form square or rectangular inductor components (FIG. 6E). In some examples, the individual components can be applied to a reel for integration into a conventional assembly process. An advantage of the methods discussed above is that the thickness of the magnetic material coated wire inductor components much thinner than other solutions that use iron or ferrite powders. Iron or ferrite powders based inductor components can require a quantity of material that necessitates a thicker component to match an inductance target that a significantly thinner magnetic material coated wire inductor component can attain. In an example, testing has shown that the inductance of an iron or ferrite powder inductor component having a thickness of 200 μm can be achieved using a magnetic material coated wire inductor component having a thickness of 100 μm.

FIG. 7 illustrates generally an integrated circuit system 740 including one or more example inductive components 741. In certain examples, the integrated circuit system 740 can include a central processor unit (CPU) 742 or gate array that includes one or more first portions 743 of a voltage regulator, a package die 744, and one or more example inductive components 741a, 741b. In certain examples, the example inductive components 741a, 741b can second portions part of the integrated voltage regulator circuits of the CPU chip 742 or gate array chip. In certain examples, the example inductive components 741a can be integrated with the package die 744. In some examples, the inductor components 741b can optionally be mounted to a surface of the package die 744. In certain examples, the package die 744 can include a core comprising a thick, rigid dielectric. Metal routing layers, like a printed circuit board, can be fabricated on the sides of the core. Multiple routing layers would typically be built up on the major sides of the core layer. The CPU 742 or gate array can be on top of the package die 744. The inductor components 741a, 741b can be placed either in a hole cut in the core layer, or soldered to the bottom of the package die 742 which can also include solder balls 745 for connecting the integrated circuit system to other components. In some examples, the example inductor components 741a, 741b can form at least a part of a filter

### Additional Examples and Notes

In Example 1, an inductor apparatus can include a wire and a plurality of individual layers of high permeability, magnetic material surrounding the wire.

In Example 2, the plurality of individual layers of high permeability, magnetic material of Example 1 optionally are electrically insulated from the wire by a layer of insulation.

In Example 3, each individual layer of high relative-permeability, magnetic material of the plurality of individual layers of any one or more of Examples 1-2 optionally is electrically insulated from an adjacent layer of high permeability, magnetic material by an individual layer of insulation.

In Example 4, an average diameter of the wire of any one or more of Examples 1-3 optionally is between 30 um and 300 um.

In Example 5, the wire of any one or more of Examples 1-4 optionally includes a copper wire.

In Example 6, the wire of any one or more of Examples 1-5 optionally includes a silver wire.

In Example 7, a first layer of insulation of any one or more of Examples 1-6 optionally is located adjacent the external surface of the wire and includes a thickness of between 1 um and 100 um.

In Example 8, each individual layer of high permeability magnetic material of any one or more of Examples 1-7 optionally includes a thickness of between 100 nm and 1 um.

In Example 9, each layer of the plurality individual layers of insulation of any one or more of Examples 1-8 optionally have a thickness of 5 nm to 100 nm.

In Example 10, the high permeability magnetic material of any one or more of Examples 1-9 optionally includes Cadmium Zinc Telluride (CZT).

In Example 11, the high permeability magnetic material of any one or more of Examples 1-10 optionally includes Cobalt, Zirconium Tantalum Boron (CZTB).

In Example 12, the high permeability magnetic material of any one or more of Examples 1-11 optionally includes a combination of nickel and iron.

In Example 13, a method can include surrounding a round length of wire with alternating layers of insulation material and high relative-permeability magnetic material to form a magnetic material coated wire inductor.

In Example 14, the surrounding the round length of wire of any one or more of Examples 1-13 optionally includes surrounding a round length of wire with alternating layers of insulation material and high relative-permeability magnetic material to form magnetic material coated wire inductor a having an average diameter between 30 um and 200 um.

In Example 15, the magnetic material of any one or more of Examples 1-14 optionally includes a polarized magnetic material.

In Example 16, the surrounding the round length of wire of any one or more of Examples 1-15 optionally includes applying a first insulating layer proximate the wire.

In Example 17, the applying the first insulating layer of any one or more of Examples 1-16 optionally includes applying a first insulating layer having a thickness of between 1 um and 100 um proximate the wire.

In Example 18, the surrounding a round length of wire with alternating layers of insulation material and magnetic material of any one or more of Examples 1-17 optionally includes spinning the wire and sputtering the magnetic material onto the spinning wire.

In Example 19, the surrounding a round length of wire with alternating layers of insulation material and magnetic material of any one or more of Examples 1-18 optionally includes applying the magnetic materials to the wire using chemical vapor deposition.

In Example 20, the surrounding a round length of wire with alternating layers of insulation material and magnetic material of any one or more of Examples 1-19 optionally includes providing a planar portion of magnetic material in a lift-off bath and lifting the planar portion of magnetic material from the lift-off bath using the wire.

In Example 21, the surrounding a round length of wire with alternating layers of insulation material and magnetic material of any one or more of Examples 1-20 optionally includes providing a planar portion of magnetic material in a lift-off bath, contacting the planar portion of magnetic material with an outer layer of insulation of a partial assembly of the magnetic material coated wire inductor, and rotating the partial assembly of the magnetic material coated wire inductor to wrap the magnetic material around the outer layer to form an additional layer of magnetic material.

Each of these non-limiting examples can stand on its own, or can be combined with one or more of the other examples in any permutation or combination.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of“at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. §1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are legally entitled.

1. An inductor apparatus comprising:
a wire;
a plurality of individual layers of high permeability, magnetic material surrounding the wire; and
wherein an average diameter of the inductor is between 30 um and 200 um.

2. The inductor apparatus of claim 1, wherein the plurality of individual layers of high permeability, magnetic material are electrically insulated from the wire by a layer of insulation.

3. The inductor apparatus of claim 1, wherein each individual layer of high relative-permeability, magnetic material of the plurality of individual layers is electrically insulated from an adjacent layer of high permeability, magnetic material by an individual layer of insulation.

4. The inductor apparatus of claim 1, wherein an average diameter of the wire is between 30 um and 300 um.

5. The inductor apparatus of claim 4, wherein the wire includes a copper wire.

6. The inductor apparatus of claim 4, wherein the wire includes a silver wire.

7. The inductor apparatus of claim 1, wherein a first layer of insulation is located adjacent the external surface of the wire and includes a thickness of between 1 um and 100 um.

8. The inductor apparatus of claim 1, wherein each individual layer of high permeability magnetic material includes a thickness of between 100 nm and 1 um.

9. The inductor apparatus of claim 1, wherein each layer of the plurality individual layers of insulation have a thickness of 5 nm to 100 nm.

10. The inductor apparatus of claim 1, wherein the high permeability magnetic material includes Cadmium Zinc Telluride (CZT).

11. The inductor apparatus of claim 1, wherein the high permeability magnetic material includes Cobalt, Zirconium Tantalum Boron (CZTB).

12. The inductor apparatus of claim 1, wherein the high permeability magnetic material includes a combination of nickel and iron.

13. A method comprising:
surrounding a round length of wire with alternating layers of insulation material and high relative-permeability magnetic material to form a magnetic material coated wire inductor.

14. The method of claim 13, wherein the surrounding the round length of wire includes surrounding a round length of wire with alternating layers of insulation material and high relative-permeability magnetic material to form magnetic material coated wire inductor a having an average diameter between 30 um and 200 um.

15. The method of claim 13, wherein the magnetic material includes a polarized magnetic material.

16. The method of claim 13, wherein surrounding the round length of wire includes applying a first insulating layer proximate the wire.

17. The method of claim 16, wherein applying the first insulating layer includes applying a first insulating layer having a thickness of between 1 um and 100 um proximate the wire.

18. The method of claim 13, wherein surrounding a round length of wire with alternating layers of insulation material and magnetic material includes:
spinning the wire; and
sputtering the magnetic material onto the spinning wire.

19. The method of claim 13, wherein surrounding a round length of wire with alternating layers of insulation material and magnetic material includes applying the magnetic materials to the wire using chemical vapor deposition.

20. The method of claim 13, wherein surrounding a round length of wire with alternating layers of insulation material and magnetic material includes:
providing a planar portion of magnetic material in a lift-off bath; and
lifting the planar portion of magnetic material from the lift-off bath using the wire.

21. The method of claim 13, wherein surrounding a round length of wire with alternating layers of insulation material and magnetic material includes:
providing a planar portion of magnetic material in a lift-off bath;
contacting the planar portion of magnetic material with an outer layer of insulation of a partial assembly of the magnetic material coated wire inductor; and
rotating the partial assembly of the magnetic material coated wire inductor to wrap the magnetic material around the outer layer to form an additional layer of magnetic material.
